(19) United States
(12) Patent Application Publication
(10) Pub. No.: US 2024/0021577 A1
(43) Pub. Date: Jan. 18, 2024

(54) SEMICONDUCTOR PACKAGE

(71) Applicant: SAMSUNG ELECTRONICS CO., LTD., Suwon-si (KR)

(72) Inventors: Yanggyoo Jung, Suwon-si (KR); Seokgeun Ahn, Suwon-si (KR); Younglyong Kim, Suwon-si (KR)

(73) Assignee: SAMSUNG ELECTRONICS CO., LTD., Suwon-si (KR)

(21) Appl. No.: 18/121,374

(22) Filed: Mar. 14, 2023

(30) Foreign Application Priority Data
Jul. 15, 2022 (KR) 10-2022-0087384

(51) Int. Cl. H01L 25/065; H10B 80/00; H01L 23/31; H01L 23/498; H01L 23/538; H01L 23/00

(52) U.S. Cl. CPC H01L 25/0655; H10B 80/00; H01L 23/3135; H01L 23/49827; H01L 23/5386; H01L 23/49816; H01L 24/08; H01L 24/13; H01L 24/16; H01L 2224/08112; H01L 2224/13147; H01L 2224/16227; H01L 2924/1431; H01L 2924/1437; H01L 2924/1436; H01L 2924/1438; H01L 2924/182

(57) ABSTRACT

In some embodiments, a semiconductor package includes a package substrate, a plurality of semiconductor chips on the package substrate, a plurality of interposers between the package substrate and the plurality of semiconductor chips, and a molding layer in contact with the plurality of semiconductor chips and the plurality of interposers. The plurality of semiconductor chips includes a first semiconductor chip, and a second and a third semiconductor chip spaced apart from the first semiconductor chip in horizontal directions. The plurality of interposers includes a first vertical connection interposer vertically overlapping the first semiconductor chip, a second vertical connection interposer vertically overlapping the second semiconductor chip, a first horizontal connection interposer vertically overlapping the first and the second semiconductor chips, and a second horizontal connection interposer vertically overlapping the second and the third semiconductor chips.

### CROSS-REFERENCE TO RELATED APPLICATION

This application claims benefit of priority under 35 U.S.C. § 119 to Korean Patent Application No. 10-2022-0087384, filed on Jul. 15, 2022, in the Korean Intellectual Property Office, the disclosure of which is incorporated by reference herein in its entirety.

### BACKGROUND

### 1. Field

The present disclosure generally relates to a semiconductor package, and more particularly, to a semiconductor package including a plurality of semiconductor chips.

### 2. Description of Related Art

According to the rapid development in the electronics industry and needs of users, related electronic devices are becoming smaller, more multifunctional, and larger in capacity. Accordingly, there is a demand for semiconductor packages including a plurality of semiconductor chips. For example, there is an increased demand for a method of mounting several types of semiconductor chips side by side on a package substrate, a method of stacking semiconductor chips or packages on one package substrate, a method of mounting an interposer including a plurality of semiconductor chips on a package substrate, and the like.

Consequently, there exists a need for further improvements in semiconductor packages that include a plurality of semiconductor chips.

### SUMMARY

The present disclosure provides for a semiconductor package including a plurality of semiconductor chips.

According to an aspect of the present disclosure, a semiconductor package is provided. The semiconductor package includes a package substrate, a plurality of semiconductor chips on the package substrate, a plurality of interposers between the package substrate and the plurality of semiconductor chips, and a molding layer in contact with the plurality of semiconductor chips and the plurality of interposers. The plurality of semiconductor chips includes a first semiconductor chip, a second semiconductor chip spaced apart from the first semiconductor chip in a first horizontal direction, and a third semiconductor chip spaced apart from the first semiconductor chip in a second horizontal direction. Each of the plurality of interposers are spaced apart from each other in a lateral direction. The plurality of interposers include a first vertical connection interposer vertically overlapping the first semiconductor chip, a second vertical connection interposer vertically overlapping the second semiconductor chip, a first horizontal connection interposer vertically overlapping a portion of the first semiconductor chip and a first portion of the second semiconductor chip, and a second horizontal connection interposer vertically overlapping a second portion of the second semiconductor chip and a portion of the third semiconductor chip. The first vertical connection interposer includes a first through-electrode configured to electrically couple the first semiconductor chip to the package substrate. The second vertical connection interposer includes a second through-electrode configured to electrically couple the second semiconductor chip to the package substrate. The first horizontal connection interposer includes a first conductive connection structure configured to electrically couple the first semiconductor chip to the second semiconductor chip. The second horizontal connection interposer includes a second conductive connection structure configured to electrically couple the second semiconductor chip to the third semiconductor chip.

According to an aspect of the present disclosure, a semiconductor package is provided. The semiconductor package includes a package substrate, a plurality of interposers on the package substrate, a plurality of semiconductor chips, first bump structures between the plurality of interposers and the plurality of semiconductor chips, and a molding layer in contact with the plurality of semiconductor chips and the plurality of interposers. The plurality of interposers include a first vertical connection interposer, a second vertical connection interposer, and a first horizontal connection interposer. The plurality of semiconductor chips includes a first semiconductor chip electrically coupled to the package substrate through the first vertical connection interposer and a second semiconductor chip electrically coupled to the package substrate through the second vertical connection interposer. The first semiconductor chip is electrically coupled to the second semiconductor chip through a conductive connection structure of the first horizontal connection interposer. The first bump structures include conductive pillars in contact with the plurality of interposers and first solder layers extending from the conductive pillars to the plurality of semiconductor chips.

According to an aspect of the present disclosure, a semiconductor package is provided. The semiconductor package includes a package substrate, a plurality of semiconductor chips on the package substrate, a plurality of interposers between the package substrate and the plurality of semiconductor chips, first bump structures between the plurality of semiconductor chips and the plurality of interposers, second bump structures between the plurality of interposers and the package substrate, and a molding layer in contact with a sidewall of each of the plurality of semiconductor chips and a sidewall of each of the plurality of interposers. The plurality of semiconductor chips include a first logic chip, a memory chip spaced apart from the first logic chip in a first horizontal direction, and a second logic chip spaced apart from the first logic chip in a second horizontal direction. Each of the plurality of interposers are spaced apart from each other in a lateral direction. The plurality of interposers include a first vertical connection interposer vertically overlapping the first logic chip, a second vertical connection interposer vertically overlapping the memory chip, a first horizontal connection interposer vertically overlapping a first portion of the first logic chip and a first portion of the memory chip, and a second horizontal connection interposer vertically overlapping a second portion of the first logic chip and a second portion of the second logic chip. The first vertical connection interposer includes a first through-electrode configured to electrically couple the first logic chip to the package substrate. The second vertical connection interposer includes a second through-electrode configured to electrically couple the memory chip to the package substrate. The first horizontal connection interposer includes a first conductive connection structure configured to electrically couple the first logic chip to the memory chip. The second horizontal connection interposer includes a second conductive connection structure configured to electrically couple the first logic chip to the second logic chip. The first horizontal connection interposer is disposed between the first vertical connection interposer. The second vertical connection interposer in the first horizontal direction. The second horizontal connection interposer is spaced apart from the first vertical connection interposer in the second horizontal direction.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description, taken in conjunction with the accompanying drawings, in which:

FIG. 1 is a plan view illustrating a semiconductor package, according to an example embodiment;

FIG. 2 is a cross-sectional view of the semiconductor package taken along line II-II′ of FIG. 1, according to an example embodiment;

FIG. 3 is a cross-sectional view of the semiconductor package taken along line III-III′ of FIG. 1, according to an example embodiment;

FIG. 4 is a cross-sectional view illustrating a part of a semiconductor package, according to an example embodiment;

FIG. 5 is a cross-sectional view illustrating a part of a semiconductor package, according to an example embodiment;

FIGS. 6A to 6H are cross-sectional views illustrating a method of manufacturing a semiconductor package, according to example embodiments;

FIG. 7 is a cross-sectional view illustrating a semiconductor package, according to an example embodiment;

FIG. 8 is a cross-sectional view illustrating a semiconductor package, according to an example embodiment;

FIG. 9 is a cross-sectional view illustrating a semiconductor package, according to an example embodiment;

FIG. 10 is a cross-sectional view illustrating a semiconductor package, according to an example embodiment;

FIG. 11 is a cross-sectional view illustrating a semiconductor package, according to an example embodiment;

FIGS. 12A to 12H are cross-sectional views illustrating a method of manufacturing a semiconductor package, according to example embodiments;

FIG. 13 is a cross-sectional view illustrating a semiconductor package, according to an example embodiment; and

FIGS. 14A to 14E are cross-sectional views illustrating a method of manufacturing the semiconductor package of FIG. 13, according to example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, expressions such as “at least one of” when preceding a list of elements, modify the entire list of elements and do not modify the individual elements of the list. For example, “at least one of a, b, and c” should be understood as including only a, only b, only c, both a and b, both a and c, both b and c, or all of a, b, and c. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, etc. may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, etc. may be used to distinguish components from each other and do not limit the present disclosure. For example, the terms “first”, “second”, “third”, etc. may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

Hereinafter, embodiments of the present disclosure are described in detail with reference to the accompanying drawings. The same reference numerals are used for the same components in the drawings, and duplicate descriptions thereof are omitted.

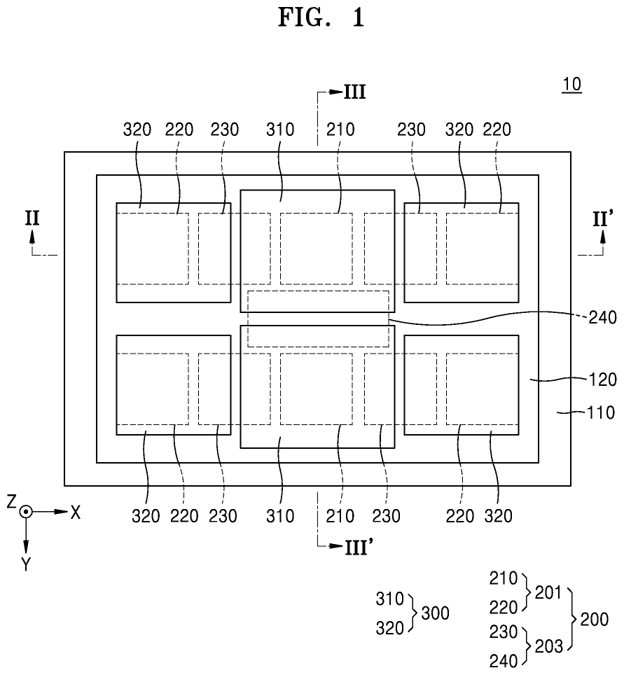

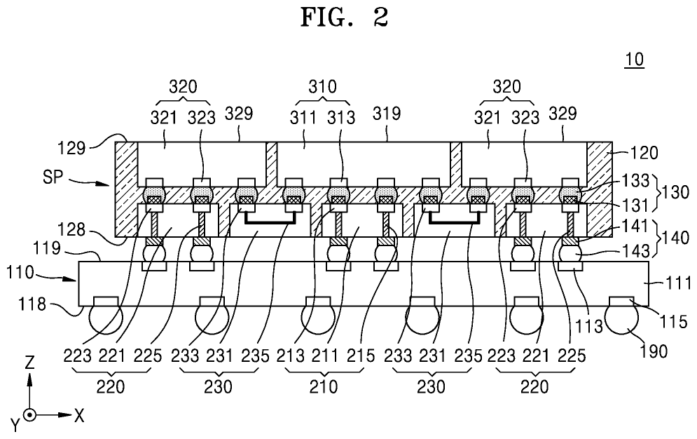

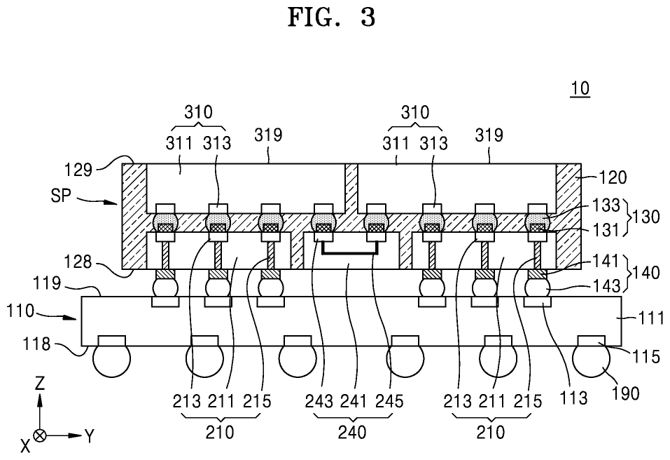

FIG. 1 is a plan view illustrating a semiconductor package 10, according to an example embodiment. FIG. 2 is a cross-sectional view of the semiconductor package 10 taken along line II-IF of FIG. 1. FIG. 3 is a cross-sectional view of the semiconductor package 10 taken along line III-III′ of FIG. 1.

Referring to FIGS. 1 to 3, the semiconductor package 10 may include a package substrate 110, a plurality of interposers 200 arranged on the package substrate 110 and spaced apart from each other in a lateral direction, a plurality of semiconductor chips 300 arranged on the plurality of interposers 200 and spaced apart from each other in the lateral direction, a molding layer 120 for molding the plurality of interposers 200 and the plurality of semiconductor chips 300, chip-interposer bump structures 130 arranged between the plurality of interposers 200 and the plurality of semiconductor chips 300, and substrate-interposer bump structures 140 arranged between the plurality of interposers 200 and the package substrate 110.

The plurality of interposers 200 may include a plurality of vertical connection interposers 201 configured to electrically connect (e.g., couple) the plurality of semiconductor chips 300 to the package substrate 110, and a plurality of horizontal connection interposers 203 configured to electrically connect (e.g., couple) two or more semiconductor chips 300 to each other. The vertical connection interposer 201 and the horizontal connection interposer 203 may have different structures and functions from each other. For example, the vertical connection interposer 201 may include a through-electrode for electrical connection in a vertical direction (e.g., the Z direction), and the horizontal connection interposer 203 may be distinguished from the vertical connection interposer 201 in that the horizontal connection interposer 203 does not include a through-electrode. For example, the horizontal connection interposer 203 may include a conductive connection structure for electrical connection between two adjacent semiconductor chips 300, and the vertical connection interposer 201 may be distinguished from the horizontal connection interposer 203 in that the vertical connection interposer 201 does not include a conductive connection structure.

In example embodiments, the plurality of interposers 200, the plurality of semiconductor chips 300, the molding layer 120, the chip-interposer bump structures 130, and the substrate-interposer bump structures 140 may constitute a sub-package SP. The sub-package SP may constitute an independent semiconductor package mounted on the package substrate 110.

The package substrate 110 may have a flat plate shape and/or a panel shape. The package substrate 110 may include an upper surface 119 and a lower surface 118, which are opposite to each other. The upper surface 119 and the lower surface 118 may each be a flat surface. Hereinafter, a horizontal direction (e.g., an X direction and/or a Y direction) may refer to a direction parallel to the upper surface 119 of the package substrate 110, and a vertical direction (e.g., the Z direction) may refer to a direction perpendicular to the upper surface 119 of the package substrate 110. Alternatively or additionally, a horizontal width may refer to a length in the horizontal direction (e.g., the X-direction and/or the Y-direction).

The package substrate 110 may be, for example, a printed circuit board (PCB). The package substrate 110 may include a core insulating layer 111, upper connection pads 113, and lower connection pads 115.

The core insulating layer 111 may include, but not be limited to, at least one material selected from among a phenol resin, an epoxy resin, and a polyimide. For example, the core insulating layer 111 may include, but not be limited to, at least one material selected from among polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The upper connection pads 113 may be provided on an upper surface of the core insulating layer 111. The lower connection pads 115 may be provided on a lower surface of the core insulating layer 111. Internal interconnect lines electrically connecting the upper connection pads 113 to the lower connection pads 115 may be provided in the core insulating layer 111. For example, the upper connection pads 113 and the lower connection pads 115 may include metal, such as, but not limited to, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

External connection terminals 190 may be respectively attached to the lower connection pads 115 of the package substrate 110. The external connection terminals 190 may electrically and/or physically connect the package substrate 110 to an external device. The external connection terminals 190 may be configured as, for example, a solder ball or a solder bump.

The plurality of semiconductor chips 300 may include different types of semiconductor chips. The plurality of semiconductor chips 300 may be electrically connected to each other through the plurality of interposers 200 and/or the package substrate 110. The plurality of semiconductor chips 300 may include, but not be limited to, a memory chip, a logic chip, a system on chip (SOC), a power management integrated circuit (PMIC) chip, a radio frequency integrated circuit (RFIC) chip, and the like. The memory chip may include, but not be limited to, a dynamic random access memory (DRAM) chip, a static random access memory (SRAM) chip, a magnetic random access memory (MRAM) chip, a NAND flash memory chip, and/or a high bandwidth memory (HBM) chip. The logic chip may include, but not be limited to, an application processor (AP), a micro-processor, a central processing unit (CPU), a controller, and/or an application specific integrated circuit (ASIC). For example, the SOC may include at least two circuits among a logic circuit, a memory circuit, a digital integrated circuit (IC), an radio-frequency IC (RFIC), and an input/output (I/O) circuit.

The plurality of semiconductor chips 300 may include one or more first semiconductor chips 310 and one or more second semiconductor chips 320. The first semiconductor chips 310 may include a logic chip. The second semiconductor chips 320 may include a memory chip, which may be the same as and/or different from the first semiconductor chips 310. For example, the first semiconductor chip 310 may include an ASIC, and the second semiconductor chip 320 may include an HBM chip. In example embodiments, the semiconductor package 10 may include two first semiconductor chips 310 and four second semiconductor chips 320. The two first semiconductor chips 310 may be arranged in a second horizontal direction (e.g., the Y direction).

In the present disclosure, any one of the two first semiconductor chips 310 may be referred to as a third semiconductor chip. One of the two first semiconductor chips 310 may have one side and the other side on which two second semiconductor chips 320 are respectively arranged. That is, the two second semiconductor chips 320 may be spaced apart from each other in the first horizontal direction (e.g., the X direction) with one first semiconductor chip 310 therebetween. However, the number and arrangement of the first semiconductor chips 310 and the number and arrangement of the second semiconductor chips 320 are not limited to the illustrations of FIGS. 1 to 3. For example, the semiconductor package 10 may also include one first semiconductor chip 310 or three or more first semiconductor chips 310, or may also include three or less second semiconductor chips 320 or five or more second semiconductor chips 320.

In example embodiments, a dimension (e.g., a width, a length, a height, a size) of the first semiconductor chip 310 may be different from a dimension of the second semiconductor chip 320. For example, a horizontal width in the first horizontal direction (e.g., the X direction) of the first semiconductor chip 310 may be different from a horizontal width in the first horizontal direction (e.g., the X direction) of the second semiconductor chip 320. Alternatively or additionally, a horizontal width in the second horizontal direction (e.g., the Y direction) of the first semiconductor chip 310 may be different from a horizontal width in the second horizontal direction (e.g., the Y direction) of the second semiconductor chip 320.

Referring to FIG. 2, the first semiconductor chip 310 may include a first semiconductor substrate 311 and a first chip pad 313. The first semiconductor substrate 311 may include an upper surface and a lower surface opposite to the upper surface. The lower surface of the first semiconductor substrate 311 may be an active surface of the first semiconductor substrate 311. The upper surface of the first semiconductor substrate 311 may be an inactive surface of the first semiconductor substrate 311.

The first semiconductor substrate 311 may be formed from a semiconductor wafer, for example. The first semiconductor substrate 311 may include, but not be limited to, silicon (Si). A semiconductor device layer including individual devices may be provided on the active surface of the first semiconductor substrate 311. The individual devices may include, but not be limited to, transistors and/or the like. The first chip pad 313 may be provided in the lower surface of the first semiconductor chip 310. The first chip pad 313 may include, but not be limited to, a conductive material, such as copper. The first chip pad 313 may be electrically connected to individual devices of the first semiconductor chip 310.

The second semiconductor chip 320 may include a second semiconductor substrate 321 and a second chip pad 323. The second semiconductor substrate 321 may include an upper surface and a lower surface opposite to the upper surfacec. The lower surface of the second semiconductor substrate 321 may be an active surface of the second semiconductor substrate 321. The upper surface of the second semiconductor substrate 321 may be an inactive surface of the second semiconductor substrate 321. The second semiconductor substrate 321 may be formed from a semiconductor wafer, for example. The second semiconductor substrate 321 may include, but not be limited to, a semiconductor, such as, Si. A semiconductor device layer including individual devices may be provided on the active surface of the second semiconductor substrate 321. The individual devices may include, but not be limited to, transistors and/or the like. The second chip pad 323 may be provided in the lower surface of the second semiconductor chip 320. The second chip pad 323 may include, but not be limited to, a conductive material, such as copper. The second chip pad 323 may be electrically connected to the individual devices of the second semiconductor chip 320.

The plurality of vertical connection interposers 201 may include a first vertical connection interposer 210 that is at least partially overlapped with the first semiconductor chip 310 in a vertical direction (e.g., the Z direction), and a second vertical connection interposer 220 that is at least partially overlapped with the second semiconductor chip 320 in the vertical direction (e.g., the Z direction).

The first vertical connection interposer 210 may be disposed between the package substrate 110 and the first semiconductor chip 310. The first vertical connection interposer 210 may electrically connect the package substrate 110 to the first semiconductor chip 310. The first semiconductor chip 310 may transmit and/or receive a power signal (e.g., a drive voltage and/or a ground voltage), a control signal, and/or an I/O data signal, and the like to and/or from the package substrate 110 through the first vertical connection interposer 210.

FIGS. 1 to 3 illustrate that one first vertical connection interposer 210 is disposed between the package substrate 110 and one first semiconductor chip 310, but two or more first vertical connection interposers 210 spaced apart from each other may also be between the package substrate 110 and one first semiconductor chip 310. Alternatively or additionally, the package substrate 110 may also be electrically connected to one first semiconductor chip 310 by two or more first vertical connection interposers 210.

The first vertical connection interposer 210 may include a first interposer substrate 211, a first through-electrode 215 penetrating through the first interposer substrate 211 in a vertical direction (e.g., the Z direction), and a first interposer connection pad 213 disposed in an upper surface of the first vertical connection interposer 210. The first vertical connection interposer 210 may be electrically and/or physically connected to the first semiconductor chip 310 by at least one of the chip-interposer bump structures 130. That is, one or more chip-interposer bump structures 130 may be disposed between the first vertical connection interposer 210 and the first semiconductor chip 310.

An upper portion of the chip-interposer bump structure 130 may be in contact with any one of the first chip pads 313 in a lower surface of the first semiconductor chip 310. Alternatively or additionally, a lower portion of the chip-interposer bump structure 130 may be in contact with the first interposer connection pad 213 of the first vertical connection interposer 210. The first vertical connection interposer 210 may be electrically and/or physically connected to the package substrate 110 by at least one of the substrate-interposer bump structures 140. That is, one or more substrate-interposer bump structures 140 may be disposed between the first vertical connection interposer 210 and the package substrate 110. An upper portion of the substrate-interposer bump structure 140 may be in contact with the first vertical connection interposer 210. Alternatively or additionally, a lower portion of the substrate-interposer bump structures 140 may be in contact with an upper connection pad 113 of the package substrate 110.

The second vertical connection interposer 220 may be disposed between the package substrate 110 and the second semiconductor chip 320 and may electrically connect the package substrate 110 to the second semiconductor chip 320. The second semiconductor chip 320 may transmit and/or receive a power signal (e.g., a drive voltage and/or a ground voltage), a control signal, and/or an I/O data signal, and the like to and/or from the package substrate 110 through the second vertical connection interposer 220.

FIGS. 1 to 3 illustrate that one second vertical connection interposer 220 is disposed between the package substrate 110 and one second semiconductor chip 320, but two or more second vertical connection interposers 220 spaced apart from each other may also be between the package substrate 110 and one second semiconductor chip 320. Alternatively or additionally, the package substrate 110 may be electrically connected to one second semiconductor chip 320 by two or more second vertical connection interposers 220.

The second vertical connection interposer 220 may include a second interposer substrate 221, a second through-electrode 225 penetrating through the second interposer substrate 221 in a vertical direction (e.g., the Z direction), and a second interposer connection pad 223 on an upper surface of the second vertical connection interposer 220. The second vertical connection interposer 220 may be electrically and/or physically connected to the second semiconductor chip 320 by at least one of the chip-interposer bump structures 130. That is, one or more chip-interposer bump structures 130 may be disposed between the second vertical connection interposer 220 and the second semiconductor chip 320. An upper portion of the chip-interposer bump structure 130 may be in contact with any one of the second chip pads 323 in a lower surface of the second semiconductor chip 320. Alternatively or additionally, a lower portion of the chip-interposer bump structure 130 may be in contact with the second interposer connection pad 223 of the second vertical connection interposer 220.

The second vertical connection interposer 220 may be electrically and/or physically connected to the package substrate 110 by at least one of the substrate-interposer bump structures 140. That is, one or more substrate-interposer bump structures 140 may be disposed between the second vertical connection interposer 220 and the package substrate 110. An upper portion of the substrate-interposer bump structure 140 may be in contact with the second vertical connection interposer 220. Alternatively or additionally, a lower portion of the substrate-interposer bump structures 140 may be in contact with an upper connection pad 113 of the package substrate 110.

The first horizontal connection interposer 230 may electrically connect the first semiconductor chip 310 to the second semiconductor chip 320. The first semiconductor chip 310 may transmit and/or receive a control signal, an I/O data signal, and/or the like to and/or from the second semiconductor chip 320 through the first horizontal connection interposer 230. The first horizontal connection interposer 230 may vertically overlap a portion of the first semiconductor chip 310 and a portion of the second semiconductor chip 320. The first horizontal connection interposer 230 may be disposed between the first vertical connection interposer 210 and the second vertical connection interposer 220 with respect to a horizontal direction (e.g., the X direction and/or the Y direction).

FIGS. 1 to 3 illustrate that one first semiconductor chip 310 is electrically connected to one second semiconductor chip 320 by one first horizontal connection interposer 230, but the present disclosure is not limited is this regard. For example, the one first semiconductor chip 310 may be electrically connected to the one second semiconductor chip 320 by two or more first horizontal connection interposers 230.

The first horizontal connection interposer 230 may include a third interposer substrate 231, third interposer connection pads 233 in an upper surface of the first horizontal connection interposer 230, and a first conductive connection structure 235 configured to electrically connect the first semiconductor chip 310 to the second semiconductor chip 320. The first conductive connection structure 235 may electrically connect the third interposer connection pad 233 overlapped with the first semiconductor chip 310 to another third interposer connection pad 233 overlapped with the second semiconductor chip 320. The first horizontal connection interposer 230 may be electrically and/or physically connected to the first semiconductor chip 310 by at least one of the chip-interposer bump structures 130. That is, one or more chip-interposer bump structures 130 may be disposed between the first horizontal connection interposer 230 and the first semiconductor chip 310. Alternatively or additionally, the first horizontal connection interposer 230 may be electrically and/or physically connected to the second semiconductor chip 320 by at least one of the chip-interposer bump structures 130. That is, one or more chip-interposer bump structures 130 may be disposed between the first horizontal connection interposer 230 and the second semiconductor chip 320.

The second horizontal connection interposer 240 may electrically connect two first semiconductor chips 310 to each other. The two first semiconductor chips 310 may transmit and/or receive control signals and/or I/O data signals through the second horizontal connection interposer 240. The second horizontal connection interposer 240 may be partially overlapped with one of the two first semiconductor chips 310 and may be partially overlapped with the other of the two first semiconductor chips 310. FIGS. 1 to 3 illustrate that the two first semiconductor chips 310 are electrically connected to each other by one second horizontal connection interposer 240, but the present disclosure is not limited in this regard. For example, the two first semiconductor chips 310 may be electrically connected to each other by the second horizontal connection interposer 240.

The second horizontal connection interposer 240 may include a fourth interposer substrate 241, fourth interposer connection pads 243 in an upper surface of the second horizontal connection interposer 240, and a second conductive connection structure 245 configured to electrically connect the two first semiconductors chips 310 to each other. The second conductive connection structure 245 may electrically connect the fourth interposer connection pad 243 overlapped with one of the two first semiconductor chips 310 to another fourth interposer connection pad 243 overlapped with the other of the two first semiconductor chips 310. The two first semiconductor chips 310 may each be electrically and/or physically connected to the second horizontal connection interposer 240 by at least one of the chip-interposer bump structures 130.

The molding layer 120 may surround sidewalls of each of the plurality of semiconductor chips 300. Alternatively or additionally, the molding layer 120 may fill a gap between two adjacent semiconductor chips 300 among the plurality of semiconductor chips 300. The molding layer 120 may cover a sidewall and a lower surface of each of the plurality of semiconductor chips 300. In example embodiments, the molding layer 120 may fully cover the sidewall of each of the plurality of semiconductor chips 300. That is, the molding layer 120 may extend from an upper end of the sidewall of each of the plurality of semiconductor chips 300 to a lower end thereof. In optional or additional embodiments, the molding layer 120 may not cover an upper surface 319 of the first semiconductor chip 310 and an upper surface 329 of the second semiconductor chip 320. In such embodiments, the upper surface 319 of the first semiconductor chip 310 and the upper surface 329 of the second semiconductor chip 320 may be exposed to the outside of the semiconductor package 10. In other optional or additional embodiments, an upper surface 129 of the molding layer 120, the upper surface 319 of the first semiconductor chip 310, and the upper surface 329 of the second semiconductor chip 320 may be coplanar with each other. In other optional or additional embodiments, a heat dissipation plate, such as a heat sink, may be attached to the upper surface 129 of the molding layer 120, the upper surface 319 of the first semiconductor chip 310, and the upper surface 329 of the second semiconductor chip 320.

The molding layer 120 may surround a sidewall of each of the plurality of interposers 200. Alternatively or additionally, the molding layer 120 may fill a gap between two adjacent interposers 200 among the plurality of interposers 200. The molding layer 120 may cover a sidewall and an upper surface of each of the plurality of interposers 200. In example embodiments, the molding layer 120 may fully cover the sidewall of each of the plurality of interposers 200. That is, the molding layer 120 may extend from an upper end of the sidewall of each of the plurality of interposers 200 to a lower end thereof. The molding layer 120 may cover a sidewall and an upper surface of the first vertical connection interposer 210, a sidewall and an upper surface of the second vertical connection interposer 220, a sidewall and an upper surface of the first horizontal connection interposer 230, and a sidewall and an upper surface of the second horizontal connection interposer 240. In example embodiments, the molding layer 120 may not cover a lower surface of the first vertical connection interposer 210, a lower surface of the second vertical connection interposer 220, a lower surface of the first horizontal connection interposer 230, and a lower surface of the second horizontal connection interposer 240. In optional or additional embodiments, a lower surface 128 of the molding layer 120, the lower surface of the first vertical connection interposer 210, the lower surface of the second vertical connection interposer 220, and the lower surface of the second horizontal connection interposer 240 may be coplanar with each other.

The molding layer 120 may fill gaps between the plurality of interposers 200 and the plurality of semiconductor chips 300. The molding layer 120 may surround sidewalls of the chip-interposer bump structures 130 between the plurality of interposers 200 and the plurality of semiconductor chips 300.

In example embodiments, the molding layer 120 may include, but not be limited to, an epoxy-based molding resin or a polyimide-based molding resin. In optional or additional embodiments, the molding layer 120, but not be limited to, may include an epoxy molding compound (EMC).

In example embodiments, the chip-interposer bump structures 130 may include conductive pillars 131 and first solder layers 133. Each of the conductive pillars 131 may have a pillar shape and may include, but not be limited to, a metal, such as copper (Cu). The first solder layers 133 may each cover at least a part of a sidewall and an upper surface of the conductive pillar 131. The conductive pillars 131 may be in contact with the plurality of interposers 200 and may be spaced apart from the plurality of semiconductor chips 300. That is, the conductive pillars 131 may be in contact with the first interposer connection pads 213 of the first vertical connection interposer 210, the second interposer connection pads 223 of the second vertical connection interposer 220, the third interposer connection pads 233 of the first horizontal connection interposer 230, and/or the fourth interposer connection pads 243 of the second horizontal connection interposer 240. Each of the first solder layers 133 may each extend between the corresponding conductive pillar 131 and a corresponding chip pad of the semiconductor chip 300.

In example embodiments, the substrate-interposer bump structures 140 may include conductive bump pads 141 and second solder layers 143. The conductive bump pads 141 may each be in contact with a lower surface of the first vertical connection interposer 210 and/or a lower surface of the second vertical connection interposer 220. The conductive bump pads 141 may each be electrically connected to the first through-electrode 215 of the first vertical connection interposer 210 and/or the second through-electrode 225 of the second vertical connection interposer 220. The second solder layers 143 may each extend between the conductive bump pad 141 and the upper connection pad 113.

In optional or additional embodiments, the substrate-interposer bump structures 140 may not be disposed between a lower surface of the first horizontal connection interposer 230 and the package substrate 110 and may be disposed between a lower surface of the second horizontal connection interposer 240 and the package substrate 110. In other optional or additional embodiments, the substrate-interposer bump structures 140 may be disposed between the lower surface of the first horizontal connection interposer 230 and the package substrate 110 and may be disposed between the lower surface of the second horizontal connection interposer 240 and the package substrate 110.

A related semiconductor package may have a structure in which a plurality of semiconductor chips are mounted on a large-area interposer having a size in which all of the plurality of semiconductor chips may be mounted. As a thickness of the large-area interposer gradually decreases, it may be difficult to control warpage caused by mismatch in coefficient of thermal expansion between individual components constituting a semiconductor package. The warpage may cause damage, such as cracks, to the semiconductor package, and accordingly, the reliability of the semiconductor package may be reduced.

However, according to an example embodiment, an electrical connection between the plurality of semiconductor chips 300 and the package substrate 110, and an electrical connection between the plurality of semiconductor chips 300 may be made by small interposers 200. Since an absolute size of warpage generated by an individual small interposer 200 is small, the warpage is relatively easily controlled, and a defect in the semiconductor package 10 due to the warpage may be removed or prevented. Accordingly, the reliability of the semiconductor package 10 may be improved.

Alternatively or additionally, in a semiconductor package product using a large-area interposer, a customized interposer may need to be designed and manufactured for each product. However, according to an example embodiment, electrical connections between the plurality of semiconductor chips 300 and the package substrate 110 and electrical connections between a plurality of semiconductor chips 300 may be made by using the small interposers 200 having different functions. As a result, the design burden of an interposer depending on products may be reduced, and a manufacturing cost may be reduced.

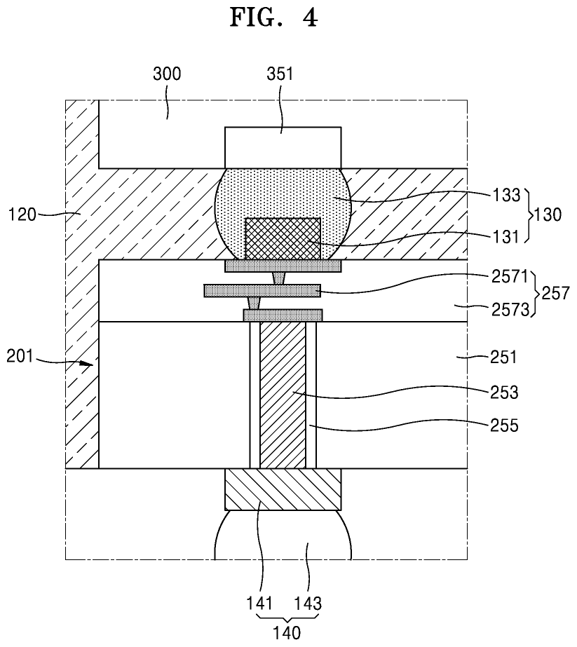

FIG. 4 is a cross-sectional view illustrating a part of a semiconductor package, according to an example embodiment.

Hereinafter, the vertical connection interposer 201, according to an example embodiment, is described with reference to FIGS. 1 to 4. Descriptions of the vertical connection interposer 201 to be described with reference to FIG. 4 may be applied to the first vertical connection interposer 210 and the second vertical connection interposer 220 described with reference to FIGS. 1 to 3.

Referring to FIG. 4, the vertical connection interposer 201 may include an interposer substrate 251, a first redistribution structure 257, and a through-electrode 253.

The interposer substrate 251 may include a silicon wafer including, but not limited to, silicon (Si), for example, crystalline silicon, polycrystalline silicon, or amorphous silicon. The interposer substrate 251 may have a substantially flat plate shape and may include an upper surface and a lower surface which is opposite to the upper surface.

The first redistribution structure 257 may be disposed on the upper surface of the interposer substrate 251. The first redistribution structure 257 may include a first insulating layer 2573 covering the upper surface of the interposer substrate 251 and a first conductive redistribution pattern 2571 covered by the first insulating layer 2573. For example, the first redistribution structure 257 may include a back-end-of-line (BEOL) structure. The first insulating layer 2573 may include, but not limited to, an organic insulating material. For example, the first insulating layer 2573 may include a photo imageable dielectric (PID), such as polyimide.

The first conductive redistribution pattern 2571 may include a plurality of conductive layers at different vertical levels within the first insulating layer 2573 to form a multilayer structure, and conductive vias extending in a vertical direction (e.g., the Z direction) in the first insulating layer 2573 to connect the plurality of conductive layers to each other. For example, the first conductive redistribution pattern 2571 may include, but not be limited to, at least one metal selected from tungsten (W), aluminum (Al), and copper (Cu). The first conductive redistribution pattern 2571 may electrically connect the chip-interposer bump structure 130 to the through-electrode 253.

A part of the first conductive redistribution pattern 2571 in an upper surface of the first redistribution structure 257 may constitute an interposer connection pad in contact with the chip-interposer bump structure 130. For example, the conductive pillar 131 of the chip-interposer bump structure 130 may be in contact with a part of the first conductive redistribution pattern 2571. In such an example, the first solder layer 133 of the chip-interposer bump structure 130 may extend between the conductive pillar 131 and a chip pad 351 of the semiconductor chip 300.

The through-electrode 253 may vertically penetrate through the interposer substrate 251. The through-electrode 253 may electrically connect the first conductive redistribution pattern 2571 to the conductive bump pad 141 of the substrate-interposer bump structure 140. The through-electrode 253 may include, but not be limited to, a metal, such as copper (Cu). A via insulating layer 255 may be disposed between the through-electrode 253 and the interposer substrate 251. The via insulating layer 255 may include, but not be limited to, an oxide film, a nitride film, a carbide film, a polymer, or a combination thereof.

In some example embodiments, the vertical connection interposer 201 may include an active device and/or a passive device. For example, the active device and/or the passive device may be provided on an upper surface of the interposer substrate 251 and may be electrically connected to the first conductive redistribution pattern 2571.

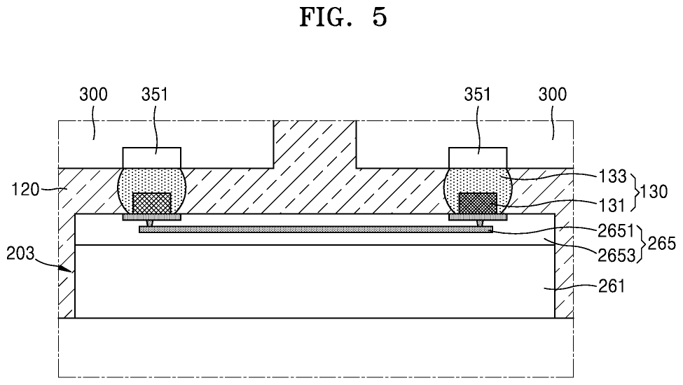

FIG. 5 is a cross-sectional view illustrating a part of a semiconductor package, according to an example embodiment.

Hereinafter, the horizontal connection interposer 203, according to an example embodiment, is described with reference to FIG. 5 and FIGS. 1 to 3. Descriptions of the horizontal connection interposer 203 made with reference to FIG. 5 may be applied to the first horizontal connection interposer 230 and the second horizontal connection interposer 240 described with reference to FIGS. 1 to 3.

Referring to FIG. 5, the horizontal connection interposer 203 may include an interposer substrate 261 and a second redistribution structure 265.

The interposer substrate 261 may include a silicon wafer including, but not be limited to, silicon (Si), for example, crystalline silicon, polycrystalline silicon, or amorphous silicon. The interposer substrate 261 may have a substantially flat plate shape and may include an upper surface and a lower surface opposite to the upper surface.

The second redistribution structure 265 may be on the upper surface of the interposer substrate 261. The second redistribution structure 265 may include a second insulating layer 2653 covering the upper surface of the interposer substrate 261, and a second conductive redistribution pattern 2651 covered by the second insulating layer 2653. For example, the second redistribution structure 265 may include a BEOL structure. The second insulating layer 2653 may include, but not be limited to, an organic insulating material. For example, the second insulating layer 2653 may include a PID such as polyimide.

The second conductive redistribution pattern 2651 may include a plurality of conductive layers at different levels within the second insulating layer 2653 to form a multilayer structure, and conductive vias extending in a vertical direction (e.g., the Z direction) within the second insulating layer 2653 to connect the plurality of conductive layers to each other. For example, the second conductive redistribution pattern 2651 may include, but not be limited to, at least one metal selected from among tungsten (W), aluminum (Al), and copper (Cu). The second conductive redistribution pattern 2651 may have a conductive connection structure configured to electrically connect two adjacent semiconductor chips 300.

A part of the second conductive redistribution pattern 2651 in an upper surface of the second redistribution structure 265 may constitute an interposer connection pad in contact with the chip-interposer bump structure 130. For example, the conductive pillar 131 of the chip-interposer bump structure 130 may be in contact with a part of the second conductive redistribution pattern 2651. In such an example, the first solder layer 133 of the chip-interposer bump structure 130 may extend between the conductive pillar 131 and the chip pad 351 of the semiconductor chip 300.

In some example embodiments, the horizontal connection interposer 203 may include an active device and/or a passive device. For example, the active device and/or the passive device may be provided on an upper surface of the interposer substrate 261 and may be electrically connected to the second conductive redistribution pattern 2651.

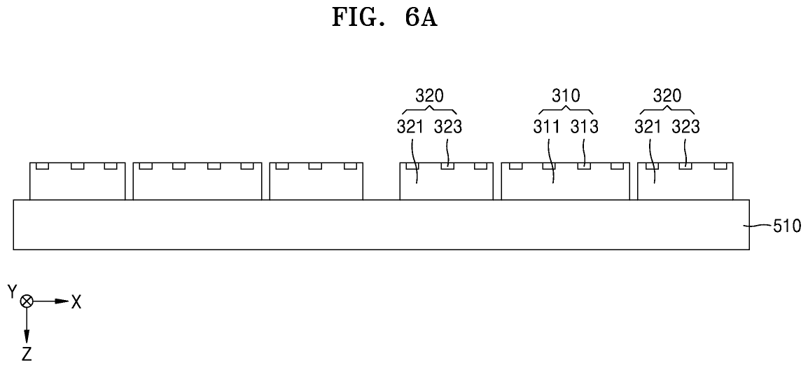

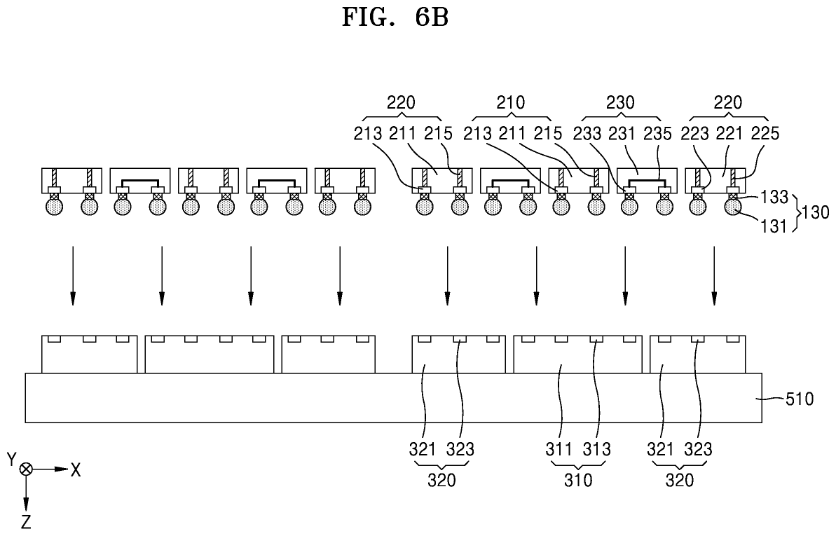

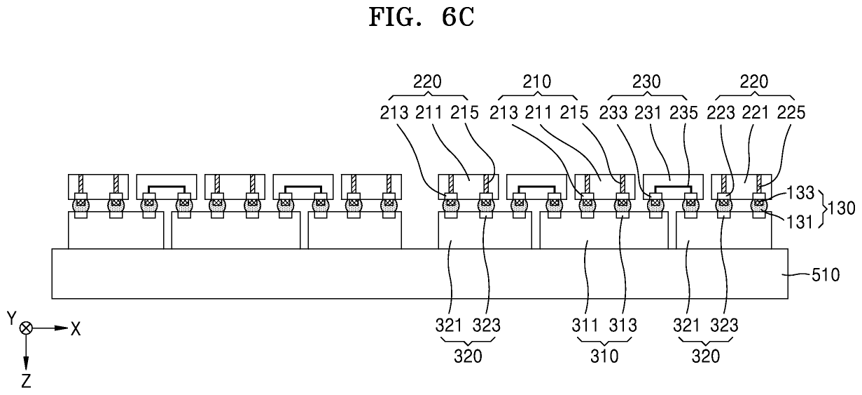

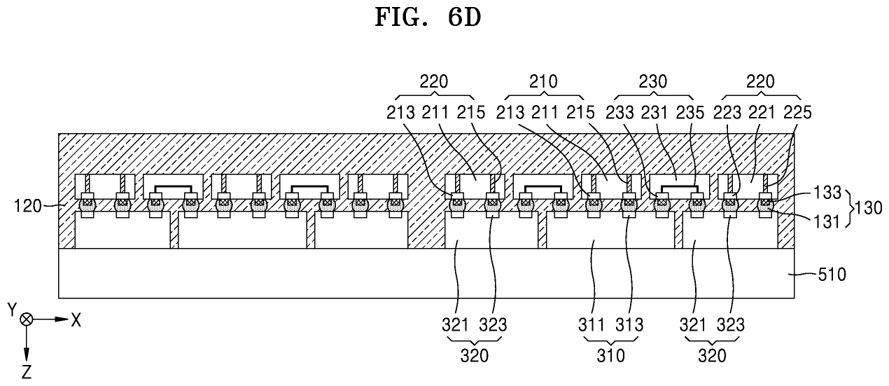

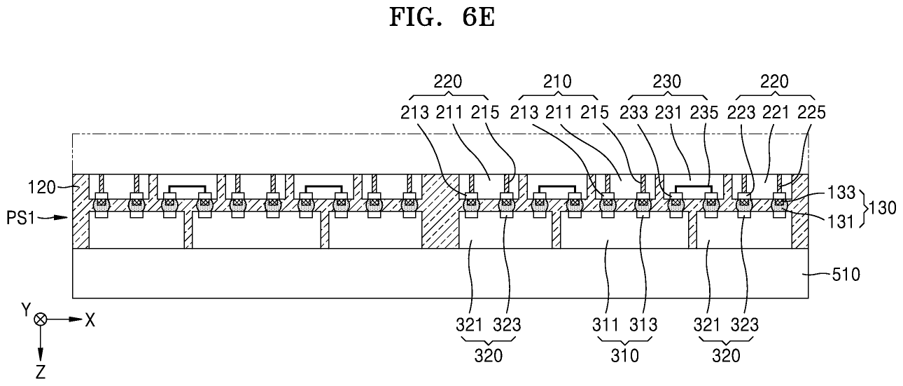

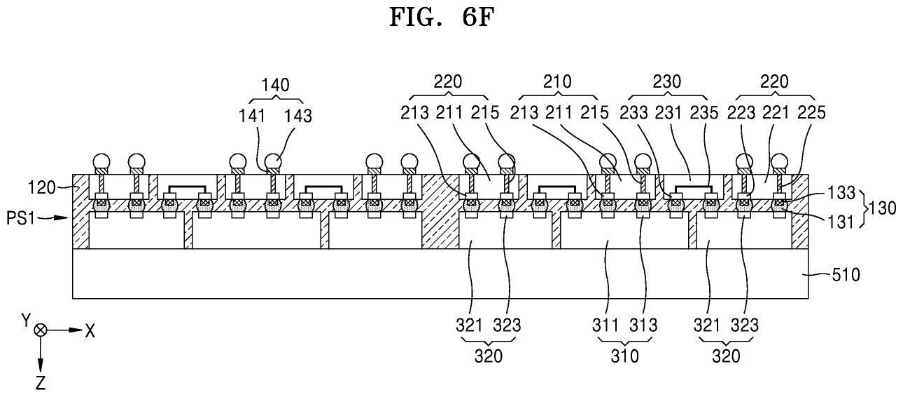

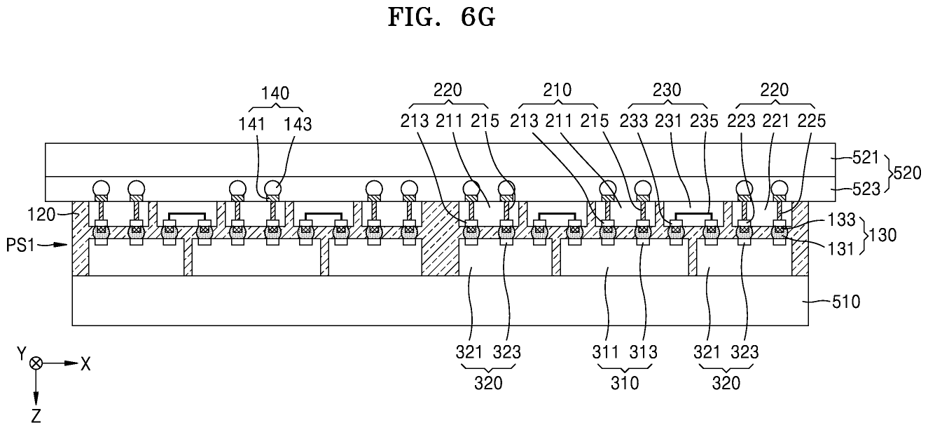

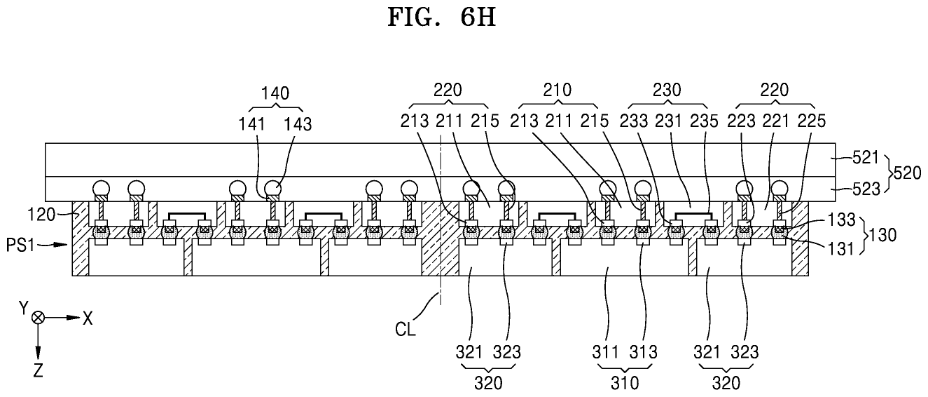

FIGS. 6A to 6H are cross-sectional views illustrating a method of manufacturing the semiconductor package 10, according to an example embodiment. Hereinafter, the method of manufacturing the semiconductor package 10 described with reference to FIGS. 1 to 3 is described with reference to FIGS. 6A to 6H.

Referring to FIG. 6A, the plurality of semiconductor chips 300 are mounted on a carrier substrate 510. That is, the first semiconductor chip 310 and the second semiconductor chip 320 may be attached to a mounting surface of the carrier substrate 510. In example embodiments, the mounting surface of the carrier substrate 510 may be a flat surface. In such embodiments, a surface of the first semiconductor chip 310 in contact with the mounting surface of the carrier substrate 510 may be coplanar with a surface of the second semiconductor chip 320 in contact with the mounting surface of the carrier substrate 510.

Referring to FIGS. 6B and 6C, a plurality of interposers 200 are mounted on the plurality of semiconductor chips 300. The plurality of interposers 200 may be mounted on the plurality of semiconductor chips 300 by using the chip-interposer bump structures 130. Mounting the plurality of interposers 200 on the plurality of semiconductor chips 300 may include preparing the plurality of interposers 200 having the chip-interposer bump structures 130, placing the plurality of interposers 200 such that the chip-interposer bump structures 130 are in contact with the chip pads of the plurality of semiconductor chips 300, and performing a thermo-compression bonding process and/or a reflow process on the chip-interposer bump structures 130.

More specifically, the mounting of the plurality of interposers 200 on the plurality of semiconductor chips 300 may include placing the first vertical connection interposer 210 including the chip-interposer bump structures 130 on the first semiconductor chip 310, placing the second vertical connection interposer 220 including the chip-interposer bump structures 130 on the second semiconductor chip 320, placing the first horizontal connection interposers 230 including the chip-interposer bump structures 130 respectively on the first semiconductor chip 310 and the second semiconductor chip 320, placing the second horizontal connection interposers 240 including the chip-interposer bump structures 130 respectively on two first semiconductor chips 310, and performing a thermo-compression bonding process or a reflow process on the chip-interposer bump structures 130.

Referring to FIG. 6D, the molding layer 120 covering the plurality of semiconductor chips 300 and the plurality of interposers 200 is formed on the carrier substrate 510. In order to form the molding layer 120, a liquid molding material may be provided on the carrier substrate 510, and then the molding material may be cured. The molding layer 120 may fill gaps between the semiconductor chips 300 adjacent in a horizontal direction (e.g., the X direction and/or the Y direction) and may fill gaps between the interposers 200 adjacent in the horizontal direction (e.g., the X direction and/or the Y direction), and fill gaps between the semiconductor chip 300 and the interposer 200 adjacent in a vertical direction (e.g., the Z direction).

Referring to FIG. 6E, a part of the molding layer 120 may be removed to expose the plurality of interposers 200. In order to remove a part of the molding layer 120, a chemical mechanical polishing (CMP) process, a grinding process, and the like may be performed. For example, a part of the molding layer 120 and a part of each of the plurality of interposers 200 may be removed through a polishing process. In example embodiments, as a result of the polishing process, a polished surface of the molding layer 120 may be coplanar with the exposed surfaces of the plurality of interposers 200. The plurality of interposers 200, the plurality of semiconductor chips 300, and the molding layer 120 may form a package structure PS1 having a flat plate shape.

Referring to FIG. 6F, the substrate-interposer bump structures 140 are formed on the exposed surfaces of the plurality of interposers 200. Forming the substrate-interposer bump structures 140 may include forming the conductive bump pads 141 that are electrically connected to the through-electrodes of the plurality of interposers 200 on the exposed surfaces of the plurality of interposers 200, and forming the second solder layers 143 on the conductive bump pads 141.

Referring to FIG. 6G, a support substrate 520 is attached onto a package structure PS1. The support substrate 520 may include a base layer 521 and an adhesive layer 523. For example, the support substrate 520 may include a debonding tape. The adhesive layer 523 may be adhered to the molding layer 120, the plurality of interposers 200, and the substrate-interposer bump structures 140. Thus, the support substrate 520 may be fixed to the package structure PS1.

Referring to FIGS. 6G and 6H, the carrier substrate 510 may be separated from the package structure PS1, and the package structure PS1 may be cut along a cutting line CL. The support substrate 520 may be separated from the package structure PS1 through a debonding process. The package structure PS1 may be separated into a plurality of sub-packages SP through a cutting process for the package structure PS1.

Referring to FIG. 2, the sub-package SP may be mounted on the package substrate 110. That is, the sub-package SP may be mounted on the package substrate 110 through the substrate-interposer bump structures 140. Mounting the sub-package SP on the package substrate 110 may include placing the sub-package SP on the package substrate 110 such that the substrate-interposer bump structures 140 are in contact with the upper connection pads 113 of the package substrate 110, and performing a thermo-compression bonding process and/or a reflow process on the substrate-interposer bump structures 140.

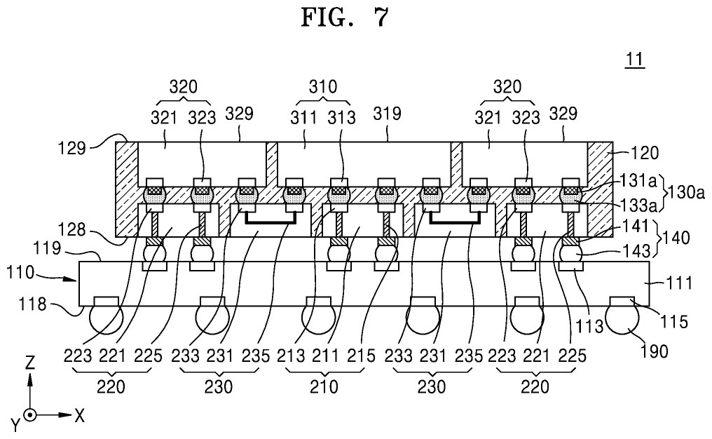

FIG. 7 is a cross-sectional view illustrating a semiconductor package 11, according to an example embodiment. Hereinafter, a difference between the semiconductor package 10 described with reference to FIGS. 1 to 3 and the semiconductor package 11 illustrated in FIG. 7 are described.

Referring to FIGS. 1 and 7, chip-interposer bump structures 130a may include conductive pillars 131a attached to lower surfaces of the plurality of semiconductor chips 300, and first solder layers 133a extending to upper surfaces of the plurality of interposers 200 from the conductive pillars 131a. The first solder layers 133a may respectively cover sidewalls and lower surfaces of the conductive pillars 131a. The conductive pillars 131a may be in contact with first chip pads 313 of the first semiconductor chip 310 and/or second chip pads 323 of the second semiconductor chip 320 and may be spaced apart from the plurality of interposers 200.

Forming the chip-interposer bump structures 130a may include mounting the plurality of semiconductor chips 300 on the carrier substrate 510 as illustrated in FIG. 6A, forming conductive pillars 131a on the chip pads of the plurality of semiconductor chips 300, and forming the first solder layer 133a on the conductive pillars 131a. Thereafter, in the mounting of the plurality of interposers 200 on the plurality of semiconductor chips 300, interposer connection pads of the plurality of interposers 200 may be attached to the first solder layers 133a.

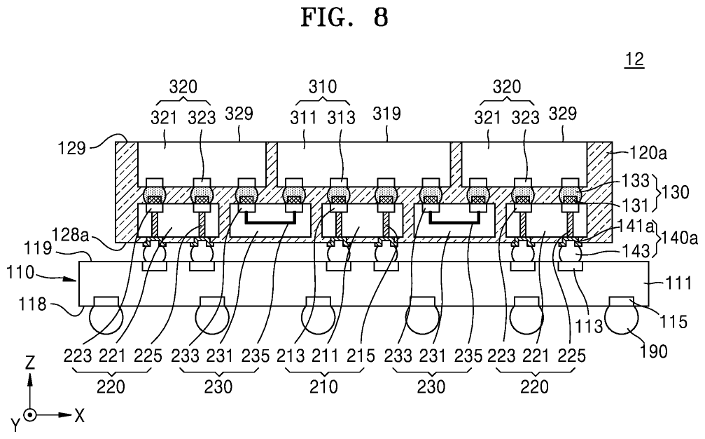

FIG. 8 is a cross-sectional view illustrating a semiconductor package 12 according to an example embodiment. Hereinafter, a difference between the semiconductor package 10 described with reference to FIGS. 1 to 3 and the semiconductor package 12 illustrated in FIG. 8 are described.

Referring to FIGS. 1 and 8, a molding layer 120a may cover lower surfaces of the plurality of interposers 200. The molding layer 120a may be in contact with the lower surfaces of the plurality of interposers 200 and may extend along the lower surfaces of the plurality of interposers 200. A vertical distance between a lower surface 128a of the molding layer 120a and an upper surface 119 of the package substrate may be smaller than a vertical distance between the lower surfaces of the plurality of interposers 200 and the upper surface 119 of the package substrate.

Substrate-interposer bump structures 140a may pass through the molding layer 120a to be in contact with interposer connection pads of the plurality of interposers 200. For example, the molding layer 120a may include an opening for partially exposing a lower surface of the first vertical connection interposer 210, and a conductive bump pad 141a may be formed to fill the opening of the molding layer 120a to be in contact with the lower surface of the first vertical connection interposer 210 exposed through the opening of the molding layer 120a.

The method of manufacturing the semiconductor package 12 may include forming the molding layer 120a covering the plurality of semiconductor chips 300 and the plurality of interposers 200 similarly to that described with reference to FIG. 6D, removing a part of the molding layer 120a such that the plurality of interposers 200 are not exposed, forming openings in the molding layer 120a to expose a part of each of the plurality of interposers 200, forming the conductive bump pads 141a in the openings of the molding layer 120a; and forming the second solder layers 143 on the conductive bump pads 141a. Forming the openings in the molding layer 120a to expose a part of each of the plurality of interposers 200 may include laser drilling, an etching process, and the like.

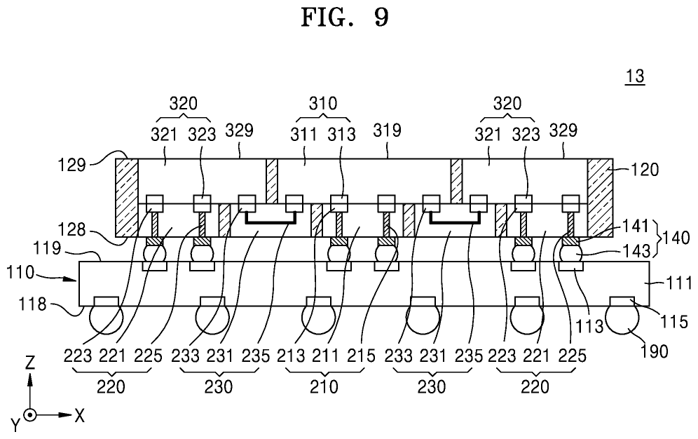

FIG. 9 is a cross-sectional view illustrating a semiconductor package 13, according to an example embodiment. Hereinafter, a difference between the semiconductor package 10 described with reference to FIGS. 1 to 3 and the semiconductor package 13 illustrated in FIG. 9 are described.

Referring to FIGS. 1 and 9, the plurality of interposers 200 may be bonded to the plurality of semiconductor chips 300 by a direct bonding method (e.g., a copper-to-copper (Cu-to-Cu) direct bonding method) and/or a hybrid bonding method. The plurality of interposers 200 may be directly connected to the plurality of semiconductor chips 300 without separate bonding media (e.g., the chip-interposer bump structures 130 of FIG. 1).

The first interposer connection pad 213 of the first vertical connection interposer 210 may be directly bonded to the corresponding first chip pad 313 of the corresponding first semiconductor chip 310. The second interposer connection pad 223 of the second vertical connection interposer 220 may be directly bonded to the corresponding second chip pad 323 of the corresponding second semiconductor chip 320. The third interposer connection pads 233 of the first horizontal connection interposer 230 may be directly bonded to the corresponding first chip pad 313 of the corresponding first semiconductor chip 310 and/or the corresponding second chip pad 323 of the corresponding second semiconductor chip 320. The fourth interposer connection pads (e.g., the fourth interposer connection pads 243 of FIG. 3) of the second horizontal connection interposer (e.g., the second horizontal connection interposer 240 of FIG. 3) may be directly bonded to the corresponding first chip pad 313 of the corresponding first semiconductor chip 310 and/or the corresponding first chip pad 313 of another corresponding first semiconductor chip 310.

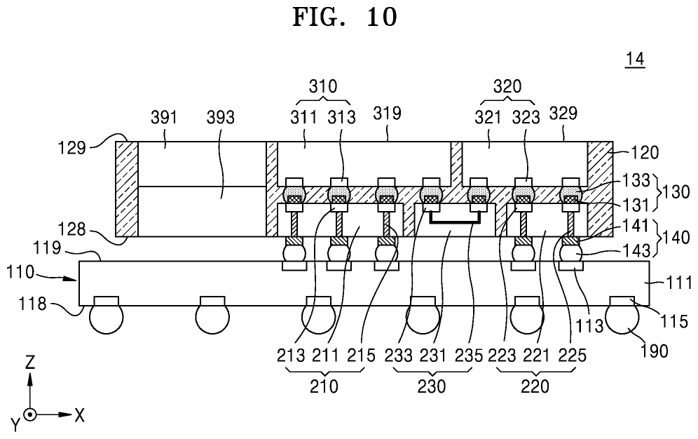

FIG. 10 is a cross-sectional view illustrating a semiconductor package 14, according to an example embodiment. Hereinafter, a difference between the semiconductor package 10 described with reference to FIGS. 1 to 3 and the semiconductor package 14 illustrated in FIG. 10 are described.

Referring to FIGS. 1 and 10, the semiconductor package 14 may further include a dummy chip in the molding layer 120. For example, the semiconductor package 14 may include a first dummy chip 391 spaced apart from the plurality of semiconductor chips 300 in a horizontal direction (e.g., the X direction and/or the Y direction), and a second dummy chip 393 spaced apart from the plurality of interposers 200 in the horizontal direction (e.g., the X direction and/or the Y direction). The first dummy chip 391 and the second dummy chip 393 may include, but not be limited to, silicon (Si). The first dummy chip 391 and the second dummy chip 393 may not be electrically connected to the plurality of semiconductor chips 300 and to the plurality of interposers 200.

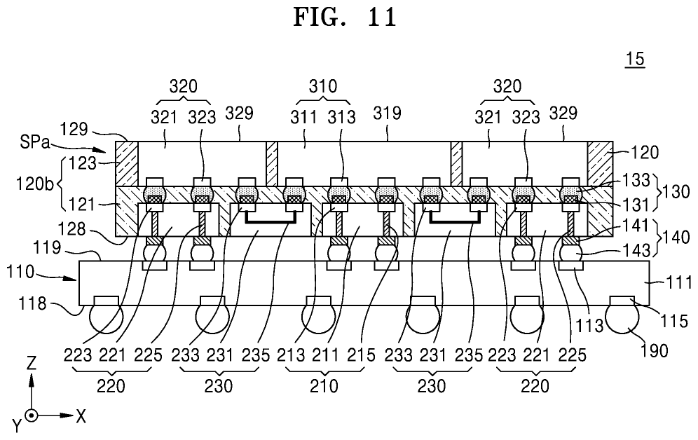

FIG. 11 is a cross-sectional view illustrating a semiconductor package 15, according to an example embodiment. Hereinafter, a difference between the semiconductor package 10 described with reference to FIGS. 1 to 3 and the semiconductor package 15 illustrated in FIG. 11 are described.

Referring to FIG. 11, a molding layer 120b may include a first molding layer 121 and a second molding layer 123.

The first molding layer 121 may surround sidewalls of the plurality of interposers 200 and may fill gaps between two adjacent interposers 200 of the plurality of interposers 200. The first molding layer 121 may fully cover the sidewalls of the plurality of interposers 200 and may extend from upper ends to lower ends of the sidewalls of each of the plurality of interposers 200. Alternatively or additionally, the first molding layer 121 may cover upper surfaces of the plurality of interposers 200 and surround sidewalls of the chip-interposer bump structures 130. In example embodiments, a lower surface of the first molding layer 121 may be coplanar with lower surfaces of the plurality of interposers 200. In optional or additional embodiments, the first molding layer 121 may cover the lower surfaces of the plurality of interposers 200.

The second molding layer 123 may be on the first molding layer 121. The second molding layer 123 may surround sidewalls of the plurality of semiconductor chips 300 and may fill gaps between two adjacent semiconductor chips 300 of the plurality of semiconductor chips 300. The first molding layer 121 may fully cover sidewalls of the plurality of semiconductor chips 300 and may extend from upper ends to lower ends of the sidewalls of each of the plurality of semiconductor chips 300. In example embodiments, an upper surface of the second molding layer 123 may be coplanar with upper surfaces of the plurality of semiconductor chips 300. In optional or additional embodiments, a lower surface of the second molding layer 123 may be coplanar with lower surfaces of the plurality of semiconductor chips 300.

The first molding layer 121 and the second molding layer 123 may include an EMC. For example, each of the first molding layer 121 and the second molding layer 123 may include a base layer formed of a resin and a filler (e.g., an inorganic filler and/or an organic filler) included in the base layer. The filler may include, but not be limited to, particles, such as silica. In example embodiments, content (and/or density) of the filler included in the first molding layer 121 may be different from content (and/or density) of the filler included in the second molding layer 123.

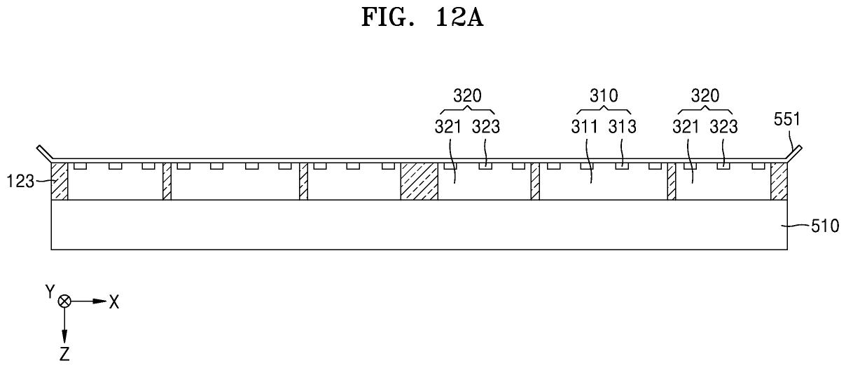

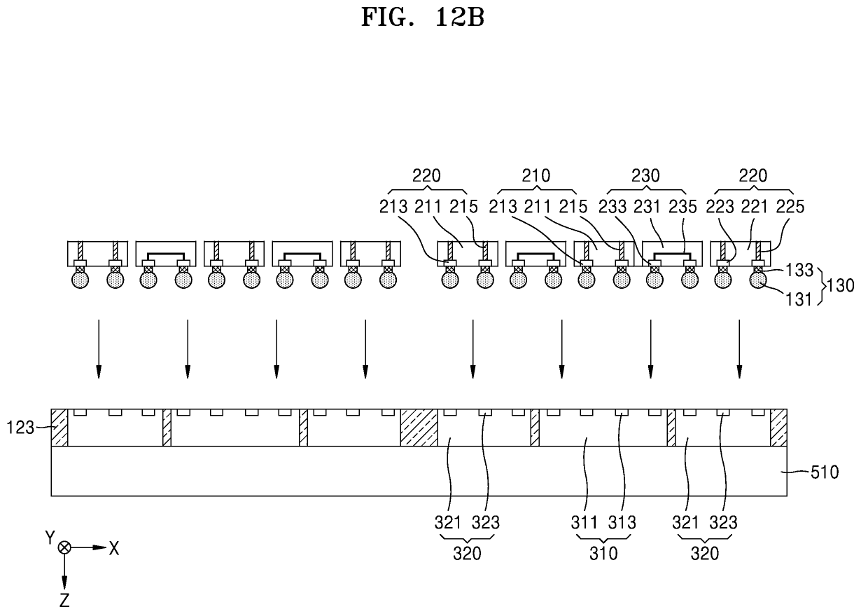

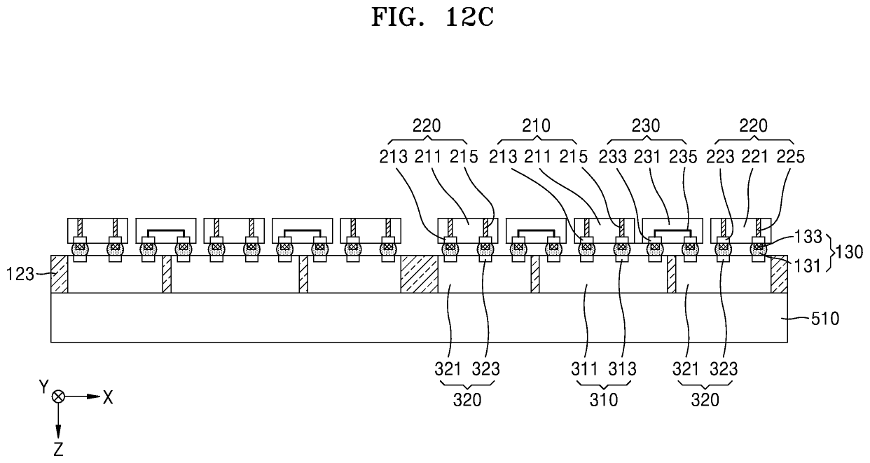

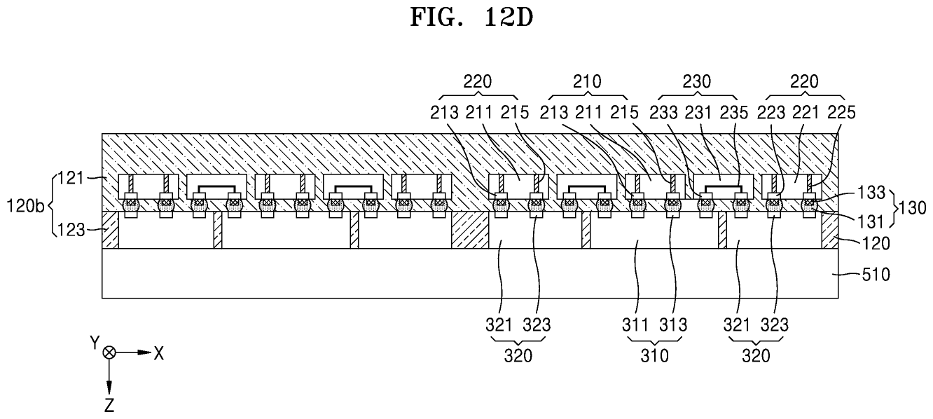

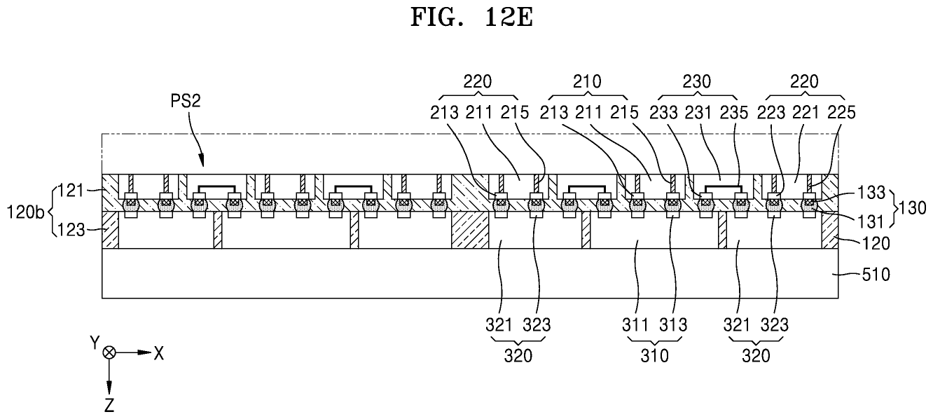

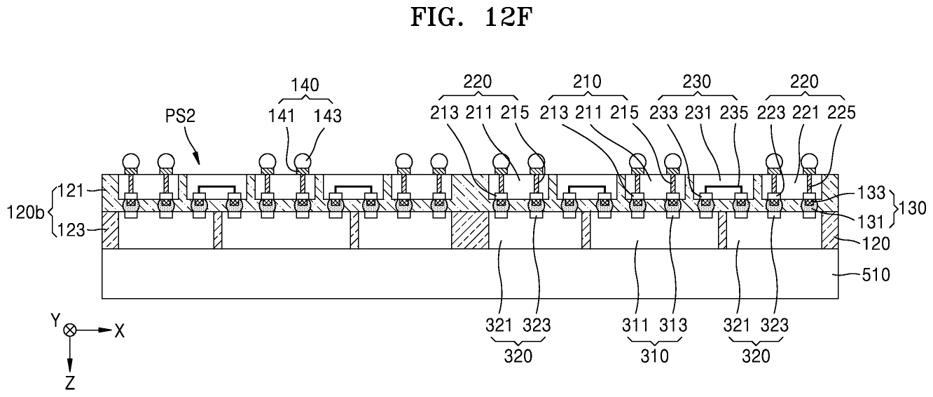

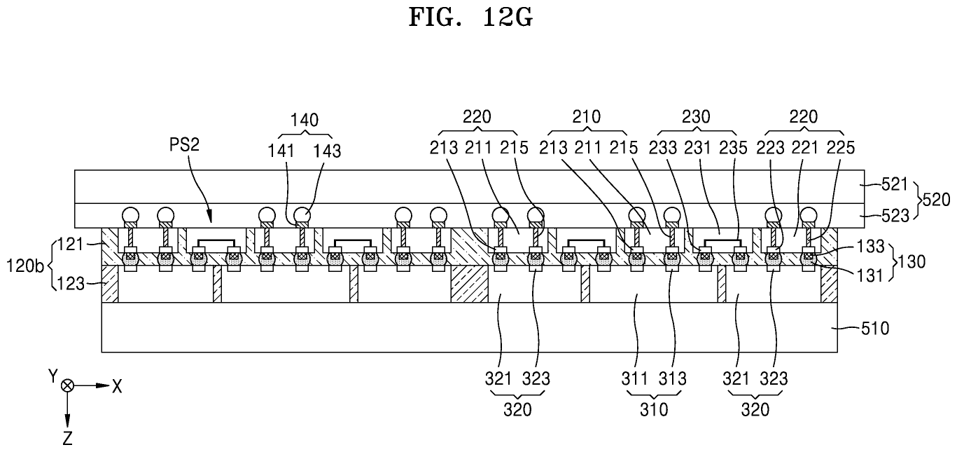

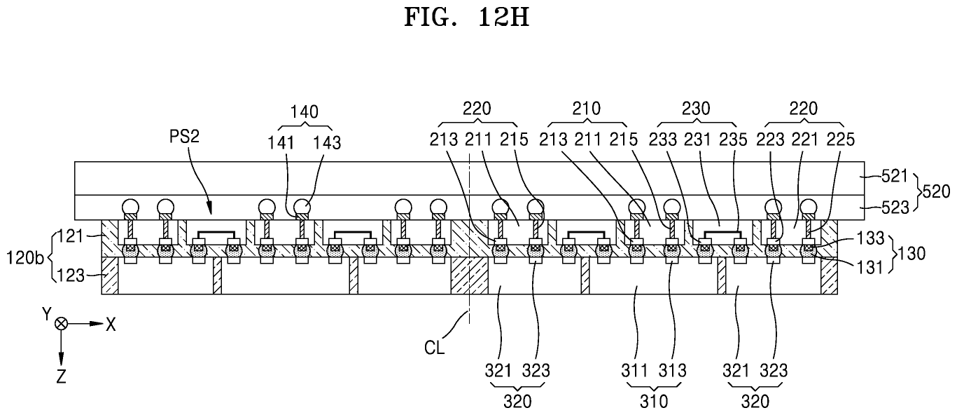

FIGS. 12A to 12H are cross-sectional views illustrating a method of manufacturing the semiconductor package 15, according to example embodiments. Hereinafter, a method of manufacturing the semiconductor package 15 described with reference to FIG. 11 are described with reference to FIGS. 12A to 12H.

Referring to FIG. 12A, the plurality of semiconductor chips 300 may be mounted on the carrier substrate 510, and the second molding layer 123 for molding the plurality of semiconductor chips 300 may be formed. For example, forming the second molding layer 123 may include attaching a molding film 551 onto the plurality of semiconductor chips 300, injecting a molding material between the plurality of semiconductor chips 300 and the carrier substrate 510, curing the molding material, and removing the molding film 551. Because the molding layer 120b is formed while the molding film 551 is attached to surfaces of the plurality of semiconductor chips 300, the surfaces of the plurality of semiconductor chips 300 may not be covered by the molding layer 120b.

Referring to FIGS. 12B and 12C, the plurality of interposers 200 may be mounted on the plurality of semiconductor chips 300. The plurality of interposers 200 may be mounted on the plurality of semiconductor chips 300 through the chip-interposer bump structures 130. Mounting the plurality of interposers 200 on the plurality of semiconductor chips 300 may include preparing the plurality of interposers 200 having the chip-interposer bump structures 130, causing the chip-interposer bump structures 130 to come into contact with chip pads of the plurality of semiconductor chips 300, and performing a thermo-compression bonding process or a reflow process on the chip-interposer bump structures 130.

Referring to FIG. 12D, the first molding layer 121 may be formed on the second molding layer 123. The first molding layer 121 may cover the plurality of interposers 200 and fill gaps between the plurality of interposers 200 and the plurality of semiconductor chips 300.

Referring to FIG. 12E, a part of the first molding layer 121 may be removed to expose the plurality of interposers 200. In order to remove a part of the first molding layer 121, a CMP process, a grinding process, and the like may be performed. For example, a part of the first molding layer 121 and a part of each of the plurality of interposers 200 may be removed through a polishing process. In example embodiments, a polished surface of the first molding layer 121 may be coplanar with the exposed surfaces of the plurality of interposers 200 as a result of the polishing process. An upper molding layer 121 and a lower molding layer 123 may form the molding layer 120b. The plurality of interposers 200, the plurality of semiconductor chips 300, and the molding layer 120b may form a package structure PS2 having a flat plate shape.

Referring to FIG. 12F, the substrate-interposer bump structures 140 may be formed on the exposed surfaces of the plurality of interposers 200.

Referring to FIG. 12G, the support substrate 520 may be attached onto the package structure PS2.

Referring to FIGS. 12G and 12H, the carrier substrate 510 may be separated from the package structure PS2, and the package structure PS2 may be cut along a cutting line CL. The support substrate 520 may be separated from the package structure PS2 through a debonding process. The package structure PS2 may be divided into a plurality of sub-packages SPa through the cutting process of the package structure PS2.

Referring to FIG. 11, the sub-package SPa may be mounted on the package substrate 110. The sub-package SPa may be mounted on the package substrate 110 through the substrate-interposer bump structures 140. Mounting the sub-packages SPa on the package substrate 110 may include placing the sub-packages SPa on the package substrate 110 such that the substrate-interposer bump structures 140 come into contact with the upper connection pads 113 of the package substrate 110, and performing a thermo-compression bonding process or a reflow process on the substrate-interposer bump structures 140.

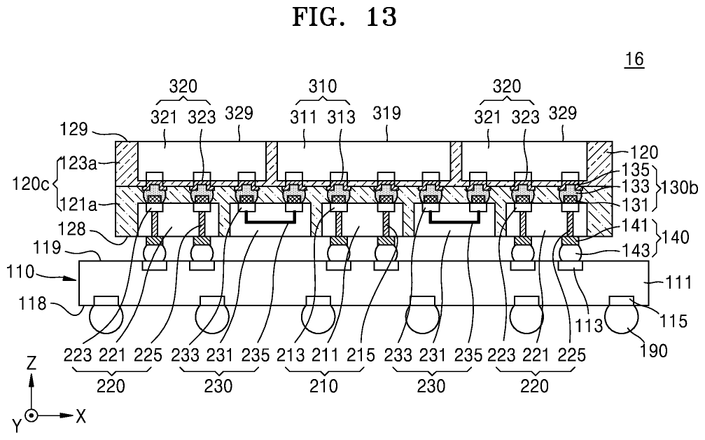

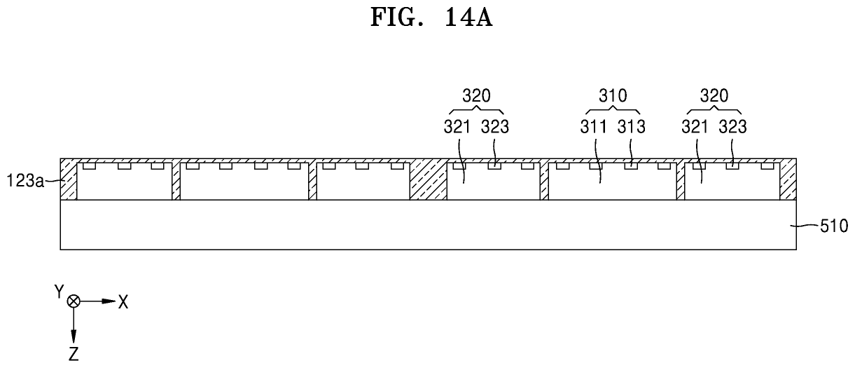

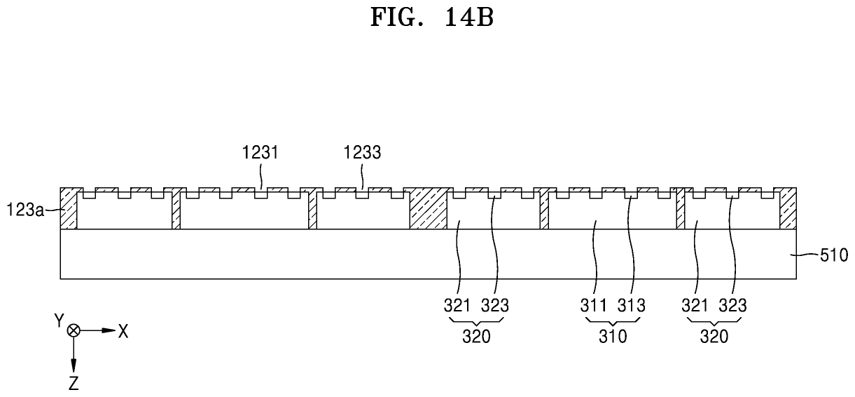

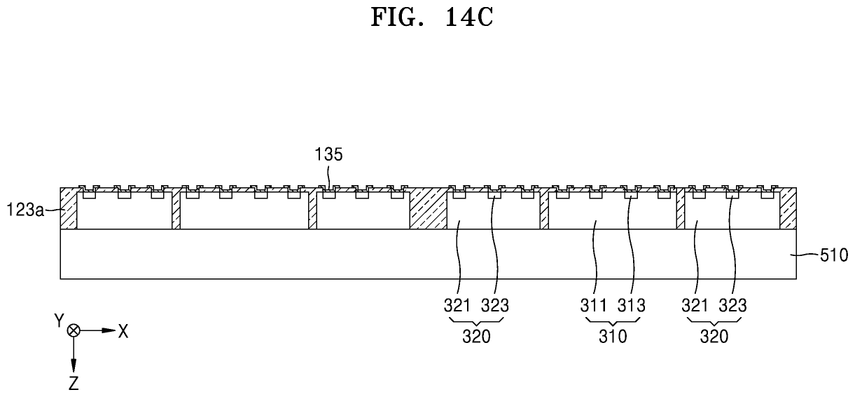

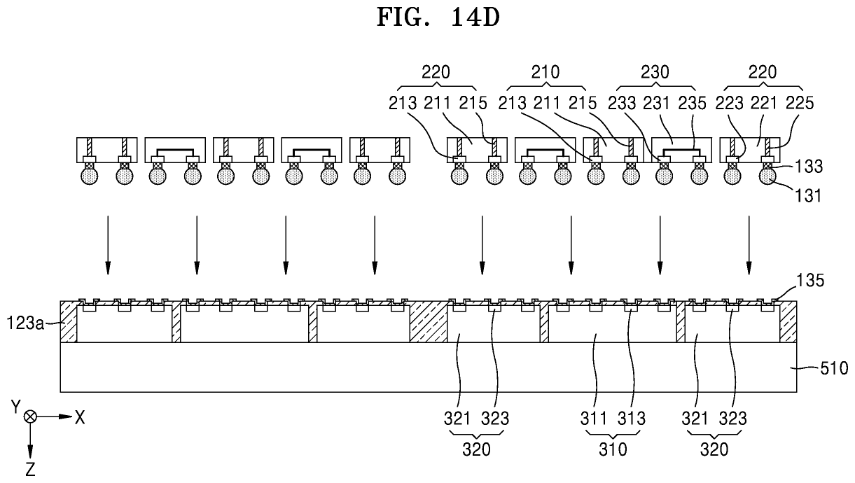

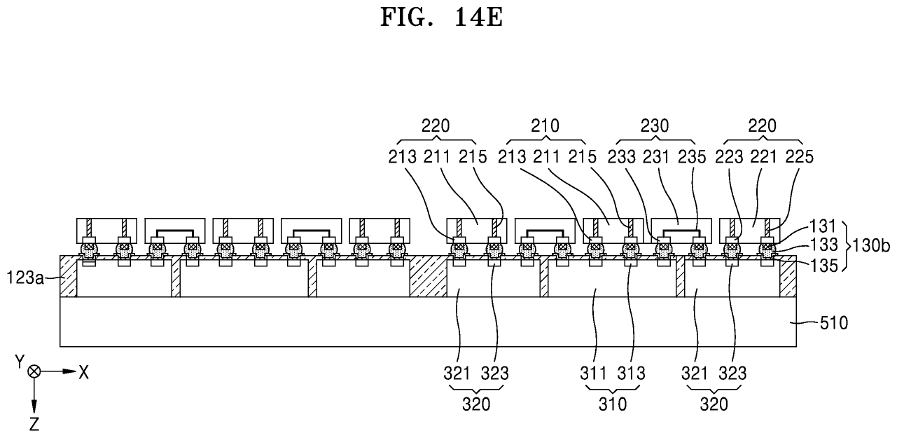

FIG. 13 is a cross-sectional view illustrating a semiconductor package 16, according to an example embodiment. FIGS. 14A to 14E are cross-sectional views illustrating a method of manufacturing the semiconductor package 16 of FIG. 13. Hereinafter, a difference between the semiconductor package 15 described with reference to FIG. 11 and the semiconductor package 16 illustrated in FIG. 13 are described.

Referring to FIGS. 1 and 13, a second molding layer 123a may cover lower surfaces of the plurality of semiconductor chips 300. The second molding layer 123a may be in contact with the lower surfaces of the plurality of semiconductor chips 300 and extend along the lower surfaces of the plurality of semiconductor chips 300. The lower surface of the second molding layer 123a may be closer to the upper surface 119 of the package substrate 110 than the lower surfaces of the plurality of semiconductor chips 300.

The chip-interposer bump structures 130b may pass through the second molding layer 123a to be in contact with chip pads of the plurality of semiconductor chips 300. The chip-interposer bump structures 130b may further include conductive bump pads 135 in contact with the chip pads of the plurality of semiconductor chips 300 through openings of the second molding layer 123a. For example, some of the conductive bump pads 135 may fill first openings of the second molding layer 123a for exposing the first chip pads 313 of the first semiconductor chip 310 to be in contact with the first chip pads 313 of the semiconductor chip 310. The remaining bump pads of the conductive bump pads 135 may fill second openings of the second molding layer 123a for exposing the second chip pads 323 of the second semiconductor chip 320 to be in contact with the second chip pads 323 of the second semiconductor chip 320.

A method of manufacturing the semiconductor package 16 may include forming the second molding layer 123a covering the plurality of semiconductor chips 300 as illustrated in FIG. 14A, forming first openings 1231 exposing the first chip pads 313 of the first semiconductor chip 310 and second openings 1233 exposing the second chip pads 323 of the second semiconductor chip 320 in the second molding layer 123a as illustrated in FIG. 14B, forming the conductive bump pads 135 in the first openings and the second openings of the second molding layer 123a as illustrated in FIG. 14C, and mounting the plurality of interposers 200 on the plurality of semiconductor chips 300 as illustrated in FIGS. 14D and 14E. In mounting the plurality of interposers 200, first solder layers 133 may be attached to the conductive bump pads 135. Forming the first openings 1231 and the second openings 1233 in the second molding layer 123a may include laser drilling, an etching process, and the like. After the mounting of the plurality of interposers 200, forming the first molding layer 121a, forming the substrate-interposer bump structures 140, cutting a package structure, and mounting sub-packages separated from the package structure on the package substrate 110 may be sequentially performed to manufacture the semiconductor package 16.

While the present disclosure has been particularly shown and described with reference to embodiments thereof, it will be understood that various changes in form and details may be made therein without departing from the spirit and scope of the following claims.

What is claimed is:

1. A semiconductor package, comprising:
a package substrate;
a plurality of semiconductor chips on the package substrate, and comprising:
a first semiconductor chip;
a second semiconductor chip spaced apart from the first semiconductor chip in a first horizontal direction; and
a third semiconductor chip spaced apart from the first semiconductor chip in a second horizontal direction;
a plurality of interposers between the package substrate and the plurality of semiconductor chips, wherein each of the plurality of interposers are spaced apart from each other in a lateral direction; and
a molding layer in contact with the plurality of semiconductor chips and the plurality of interposers,
wherein the plurality of interposers comprise:
a first vertical connection interposer vertically overlapping the first semiconductor chip, and comprising a first through-electrode configured to electrically couple the first semiconductor chip to the package substrate,
a second vertical connection interposer vertically overlapping the second semiconductor chip, and comprising a second through-electrode configured to electrically couple the second semiconductor chip to the package substrate,
a first horizontal connection interposer vertically overlapping a portion of the first semiconductor chip and a first portion of the second semiconductor chip, and comprising a first conductive connection structure configured to electrically couple the first semiconductor chip to the second semiconductor chip, and
a second horizontal connection interposer vertically overlapping a second portion of the second semiconductor chip and a portion of the third semiconductor chip, and comprising a second conductive connection structure configured to electrically couple the second semiconductor chip to the third semiconductor chip.

2. The semiconductor package of claim 1, wherein the first semiconductor chip comprises a first logic chip,
wherein the second semiconductor chip comprises a memory chip, and
wherein the third semiconductor chip comprises a second logic chip.

3. The semiconductor package of claim 1, wherein the first vertical connection interposer is disposed to prevent vertical overlap with the second semiconductor chip, and
wherein the second vertical connection interposer is disposed to prevent vertical overlap with the first semiconductor chip.

4. The semiconductor package of claim 1, further comprising first bump structures between the plurality of semiconductor chips and the plurality of interposers.

5. The semiconductor package of claim 4, wherein the first bump structures comprise:
conductive pillars in contact with the plurality of interposers; and
first solder layers in contact with sidewalls and upper surfaces of the conductive pillars.

6. The semiconductor package of claim 4, wherein the first bump structures comprise:
conductive pillars in contact with the plurality of semiconductor chips; and
first solder layers in contact with sidewalls and lower surfaces of the conductive pillars.

7. The semiconductor package of claim 1, further comprising second bump structures between the first vertical connection interposer and the package substrate and between the second vertical connection interposer and the package substrate.

8. The semiconductor package of claim 1, wherein the molding layer extends along lower surfaces of the plurality of interposers facing the package substrate.

9. The semiconductor package of claim 1, wherein a first chip pad of the first semiconductor chip is directly coupled to a first interposer connection pad of the first vertical connection interposer, and
wherein a second chip pad of the second semiconductor chip is directly coupled to a second interposer connection pad of the second vertical connection interposer.

10. The semiconductor package of claim 1, further comprising a dummy chip in the molding layer.

11. The semiconductor package of claim 1, wherein the molding layer comprises:
a first molding layer in contact with a sidewall of each of the plurality of interposers; and
a second molding layer in contact with a sidewall of each of the plurality of semiconductor chips.

12. The semiconductor package of claim 11, wherein the first molding layer is in contact with lower surfaces of the plurality of semiconductor chips facing the package substrate.

13. The semiconductor package of claim 11, wherein the second molding layer is in contact with lower surfaces of the plurality of semiconductor chips facing the package substrate.

14. A semiconductor package, comprising:
a package substrate;
a plurality of interposers on the package substrate, and comprising a first vertical connection interposer, a second vertical connection interposer, and a first horizontal connection interposer;
a plurality of semiconductor chips comprising a first semiconductor chip electrically coupled to the package substrate through the first vertical connection interposer and a second semiconductor chip electrically coupled to the package substrate through the second vertical connection interposer, the first semiconductor chip electrically coupled to the second semiconductor chip through a conductive connection structure of the first horizontal connection interposer;
first bump structures between the plurality of interposers and the plurality of semiconductor chips, the first bump structures comprising conductive pillars in contact with the plurality of interposers and first solder layers extending from the conductive pillars to the plurality of semiconductor chips; and
a molding layer in contact with the plurality of semiconductor chips and the plurality of interposers.

15. The semiconductor package of claim 14, wherein the first solder layers are in contact with sidewalls of the conductive pillars and upper surfaces of the conductive pillars facing the plurality of semiconductor chips.

16. The semiconductor package of claim 14, wherein an upper surface of the molding layer is coplanar with upper surfaces of the plurality of semiconductor chips.

17. The semiconductor package of claim 15, further comprising second bump structures attached to at least one of a lower surface of the first vertical connection interposer and a lower surface of the second vertical connection interposer,
wherein the molding layer is in contact with the lower surface of the first vertical connection interposer and the lower surface of the second vertical connection interposer.

18. The semiconductor package of claim 14, wherein the molding layer comprises a first molding layer in contact with a sidewall of each of the plurality of interposers, and a second molding layer in contact with a sidewall of each of the plurality of semiconductor chips,
wherein an upper surface of the second molding layer is coplanar with upper surfaces of the plurality of semiconductor chips, and
wherein a lower surface of the second molding layer is coplanar with lower surfaces of the plurality of semiconductor chips.

19. A semiconductor package, comprising:
a package substrate;
a plurality of semiconductor chips on the package substrate, and comprising a first logic chip, a memory chip spaced apart from the first logic chip in a first horizontal direction, and a second logic chip spaced apart from the first logic chip in a second horizontal direction;
a plurality of interposers between the package substrate and the plurality of semiconductor chips, wherein each of the plurality of interposers are spaced apart from each other in a lateral direction;
first bump structures between the plurality of semiconductor chips and the plurality of interposers;
second bump structures between the plurality of interposers and the package substrate; and
a molding layer in contact with a sidewall of each of the plurality of semiconductor chips and a sidewall of each of the plurality of interposers,
wherein the plurality of interposers comprise:
a first vertical connection interposer vertically overlapping the first logic chip and comprising a first through-electrode configured to electrically couple the first logic chip to the package substrate,
a second vertical connection interposer vertically overlapping the memory chip and comprising a second through-electrode configured to electrically couple the memory chip to the package substrate,
a first horizontal connection interposer vertically overlapping a first portion of the first logic chip and a first portion of the memory chip and comprising a first conductive connection structure configured to electrically couple the first logic chip to the memory chip, and
a second horizontal connection interposer vertically overlapping a second portion of the first logic chip and a second portion of the second logic chip and comprising a second conductive connection structure configured to electrically couple the first logic chip to the second logic chip,
wherein the first horizontal connection interposer is disposed between the first vertical connection interposer and the second vertical connection interposer in the first horizontal direction, and
wherein the second horizontal connection interposer is spaced apart from the first vertical connection interposer in the second horizontal direction.

20. The semiconductor package of claim 19, wherein the first bump structures comprise:
conductive pillars in contact with the plurality of interposers, wherein the conductive pillars comprise copper; and
solder layers extending from the conductive pillars to the plurality of semiconductor chips, wherein the solder layers are in contact with sidewalls of the conductive pillars and upper surfaces of the conductive pillars.
